(19) United States
(12) Patent Application Publication
(10) Pub. No.: US 2026/0328876 A1
(43) Pub. Date: Oct. 22, 2026

(54) MAGNET RESONANCE IMAGING (MRI) SYSTEM WITH COMBINATION LIQUID AND AIR COOLED HELIUM COMPRESSOR

(71) Applicant: KONINKLIJKE PHILIPS N.V., EINDHOVEN (NL)

(72) Inventors: Chris MUNRO, Latham, NY (US); Philippe MENTEUR, Niskayna, NY (US); Matthew VOSS, Clifton Park, NY (US); Josh HILDERBRAND, Clifton Park, NY (US)

(21) Appl. No.: 19/185,664

(22) Filed: Apr. 22, 2025

(51) Int. Cl. G01R 33/38; G01R 33/3815

(52) U.S. Cl. CPC G01R 33/3804; G01R 33/3815

(57) ABSTRACT

A magnetic resonance imaging (MRI) system includes an MRI vacuum vessel containing an MRI magnet comprising superconducting windings. A cryogenic cold head cools the superconducting windings. A compressor compresses helium gas, and supply and return helium gas lines connect the compressor with the cryogenic cold head. A liquid cooled heat exchanger is operatively connected to cool the helium gas flowing in the supply helium gas line, and supply and return liquid coolant lines are connected to flow liquid coolant through the liquid cooled heat exchanger. An air-cooled heat exchanger is also operatively connected to cool the helium gas flowing in the supply helium gas line. A temperature sensor is arranged to measure a temperature of the return liquid coolant line. The air-cooled heat exchanger includes a fan configured to be controlled by an output of the temperature sensor.

### FIELD

The following relates generally to the magnetic resonance imaging (MRI) arts, MR magnet arts, MR refrigeration system arts, MR compressor system arts, and related arts.

### BACKGROUND

Magnets for magnetic resonance imaging (MRI) systems typically employ superconducting windings, which during use are maintained at a temperature below the critical temperature for superconductivity. The critical temperature is dependent on the type of superconductor material and factors such as the maximum operational electrical current and magnetic field experienced by the superconducting windings. With most superconductors, the critical temperature is a cryogenic temperature which is significantly lower than the boiling point of liquid nitrogen (~77 K). A compressor using helium gas as working fluid is employed to refrigerate the windings below their critical temperature for superconductivity. In liquid helium filled (LHF) magnets, the superconducting windings are disposed in a vacuum-jacketed vessel which is filled with typically hundreds of liters of liquid helium. The large liquid helium reservoir provides a thermal buffer which guards against rapid increase in temperature of the superconducting windings. By contrast, low helium volume (LHV) magnets typically contain tens of liters of liquid helium in a sealed volume which substantially prevents helium boiloff. The low helium volume of an LHV magnet provides a less effective thermal buffer compared with the larger liquid helium volume of an LHF magnet. When superconducting, the coils can carry high electrical current (i.e., the coils are “energized”) with zero electrical resistance to generate a magnetic field with a magnitude sufficient for the MRI system to function. The magnets used in LHF and LVH MRI systems utilize a refrigeration system (i.e., a cryocooler, also referred to herein as a cryogenic cold head) to minimize the loss of helium due to excess heat entering the magnet and/or to keep the helium volume in its liquid state.

A potential failure mode of an MRI magnet is quench, which occurs if the magnet windings conducting the superconducting current rise in temperature above their critical temperature for superconductivity. In a quench, the magnet windings transition from their superconducting state to their resistive “normal” state, which produces rapid Joule heating that can quickly damage or destroy the MRI magnet. Accordingly, the MRI system is designed with safeguards to ensure a quench does not occur. Due to the large volume of helium in a LHF magnet, it has the thermal capacity to keep the windings below their critical temperature and thus enable the MRI system to continue scanning (i.e., continue operating to acquire MRI images) in the event that the refrigeration system becomes inoperable for a time on the scale of days. This provides significant protection against a quench, and enables operators to attempt to repair the refrigeration system (including taking it off-line for a time to effect repair) or, if necessary, to perform a controlled shutdown in which the magnet is deenergized before the windings warm up enough to cause a transition out of the superconducting state. On the other hand, an LHV magnet has much less thermal capacity due to the reduced volume of helium. In the event that the refrigeration system stops functioning, operators have a much shorter time window (e.g., hours or less) before the magnet windings must be de-energized to avoid an uncontrolled magnet quench. On the other hand, when an LHV magnet is de-energized it takes considerably more time to cool down after the repair is made when compared to an LHF magnet. This has a significant impact on the customer that owns an LHV magnet as they cannot scan when the magnet is ramped down.

MRI systems include a refrigeration system with multiple protection mechanisms to guard against magnet quench. For example, MRI systems may include a redundant “backup” compressor for the MRI magnet refrigeration system. This dual-compressor refrigeration system uses a primary, liquid cooled compressor and a backup, air cooled compressor to ensure the magnet will remain energized if the primary compressor fails for any reason, such as failure of the compressor motor of the primary compressor, loss of electrical power to the primary compressor, or if there is a loss of liquid coolant supply to the liquid-cooled heat exchanger of the primary compressor.

The following discloses certain improvements to overcome these problems and others.

### SUMMARY

In some embodiments disclosed herein, a magnetic resonance imaging (MRI) system includes an MRI vacuum vessel containing an MRI magnet comprising superconducting windings. A cryogenic cold head cools the superconducting windings. A compressor compresses helium gas, and supply and return helium gas lines connect the compressor with the cryogenic cold head. A liquid cooled heat exchanger is operatively connected to cool the helium gas flowing in the supply helium gas line, and supply and return liquid coolant lines are connected to flow liquid coolant through the liquid cooled heat exchanger. An air-cooled heat exchanger is also operatively connected to cool the helium gas flowing in the supply helium gas line. A temperature sensor is arranged to measure a temperature of the return liquid coolant line. The air-cooled heat exchanger includes a fan configured to be controlled by an output of the temperature sensor.

In some embodiments disclosed herein, an imaging system includes: a magnetic resonance imaging (MRI) vacuum vessel containing an MRI magnet comprising superconducting windings; a cryogenic cold head connected to cool the superconducting windings; a compressor configured to compress helium gas; a supply helium gas line and a return helium gas line connecting the compressor with the cryogenic cold head; a liquid cooled heat exchanger operatively connected to cool the helium gas flowing in the supply helium gas line; a supply liquid coolant line connected to flow liquid coolant into the liquid cooled heat exchanger; a return liquid coolant line connected to flow the liquid coolant out of the liquid cooled heat exchanger; and an air-cooled heat exchanger operatively connected to cool the helium gas flowing in the supply helium gas line.

In some embodiments disclosed herein, a compressed helium delivery system is provided for an MRI system. The compressed helium delivery system includes a compressor configured to compress helium gas, a supply helium gas line connected to deliver the compressed helium gas from the compressor to a cryogenic cold head of the MRI system, a liquid cooled heat exchanger operatively connected to cool the helium gas flowing in the supply helium gas line, supply and return liquid coolant lines connected to flow liquid coolant through the liquid cooled heat exchanger, and an air-cooled heat exchanger operatively connected to cool the helium gas flowing in the supply helium gas line. Some embodiments of the compressed helium delivery system further include a temperature sensor arranged to measure a temperature of the return liquid coolant line. In some such embodiments, the air-cooled heat exchanger includes a fan which is configured to be controlled by an output of the temperature sensor. In some nonlimiting illustrative examples of this control, a switch is configured to turn the fan on or off based on the output of the temperature sensor. For example, the switch may be configured to turn the fan on in response to the output of the temperature sensor exceeding or equaling a predetermined temperature threshold, and turn the fan off in response to the output of the temperature sensor underrunning the predetermined temperature threshold.

In some embodiments disclosed herein, a method of controlling operation of a magnetic resonance imaging (MRI) device is disclosed. The method comprises: compressing helium gas using a compressor connected to deliver the compressed helium gas to a cryogenic cold head of the MRI device; measuring a temperature of a return liquid coolant line of a liquid heat exchanger used to cool the compressed helium gas delivered from the compressor to the cryogenic cold head of the MRI device; determining whether the measured temperature exceeds or underruns a predetermined temperature threshold; in response to the measured temperature being determined to exceed the predetermined temperature threshold, turning on a fan of an air cooled heat exchanger to cool the compressed helium gas delivered to the cryogenic cold head of the MRI device; and in response to the measured temperature being determined to underrun the predetermined temperature threshold, turning off the fan of the air cooled heat exchanger.

In some embodiments disclosed herein, a method of controlling operation of a magnetic resonance imaging (MRI) device is disclosed. The method comprises: compressing helium gas using a compressor connected to deliver the compressed helium gas to a cryogenic cold head of the MRI device; automatically detecting whether the compressor is connected with a liquid helium filled magnet or with a low volume helium magnet; in response to the compressor being detected to be connected with a liquid helium filled magnet, operating the compressor continuously in an auto-control mode; and in response to the compressor being detected to be connected with a low volume helium magnet, disabling the auto-control mode.

One advantage resides in providing an MRI imaging device with reduced cost by employing a single compressor having both a liquid cooled heat exchanger and an air cooled heat exchanger.

Another advantage resides in providing an MRI magnet refrigeration system with reduced cost and user complexity by employing a single compressor in which the liquid cooled and air cooled heat exchangers are configured to automatically utilize the air cooled heat exchanger as a backup in response to a failure of the liquid cooled heat exchanger.

Another advantage resides in providing an MRI imaging device with an MRI magnet refrigeration system that automatically configures itself for the type of magnet (LHF or LHV) with which it is connected.

Another advantage resides in providing an autonomous compressor for an MRI imaging device.

A given embodiment may provide none, one, two, more, or all of the foregoing advantages, and/or may provide other advantages as will become apparent to one of ordinary skill in the art upon reading and understanding the present disclosure.

### BRIEF DESCRIPTION OF THE DRAWINGS

The disclosure may take form in various components and arrangements of components, and in various steps and arrangements of steps. The drawings are only for purposes of illustrating the preferred embodiments and are not to be construed as limiting the disclosure.

FIG. 1 diagrammatically illustrates a magnetic resonance imaging (MRI) device in accordance with the present disclosure.

FIGS. 2 and 3 diagrammatically illustrate MRI operation methods for operating the MRI device of FIG. 1.

### DETAILED DESCRIPTION

The following discloses an improved MRI device including an autonomous compressor system with a single compressor that includes both a liquid cooled heat exchanger and an air cooled heat exchanger. MRI magnet refrigeration systems which employ dual compressors (e.g., a primary water-cooled compressor and a backup air-cooled compressor) are generally understood in the art to be necessary for sufficient protection against inadvertent magnet quench, especially in the case of low helium volume (LHV) magnets with limited thermal buffer due to a low volume of helium. However, it is recognized herein that the additional protective value of a dual compressor MRI magnet refrigeration system is of limited value in practice, and is complicated to operate, and field technicians can have a hard time understanding how such systems work and what to expect under different circumstances. This can lead to confusion and unnecessary replacement of components of MRI devices.

It is recognized herein that the principle and dominant failure mode of a compressor is failure of the liquid cooled heat exchanger of the primary compressor. Failure of the liquid cooled heat exchanger can occur in numerous ways, such as interruption of the liquid coolant supply or clogging or blockage of the tubing of the liquid-cooled heat exchanger, Other compressor failure modes such as a failure of the compressor motor are much less common. Accordingly, in some illustrative embodiments disclosed herein, a single compressor is provided for the MRI magnet refrigeration system, and this single compressor has both a liquid cooled heat exchanger and an air-cooled heat exchanger arranged in series. In some such embodiments, control circuitry is provided to automatically activate the air-cooled heat exchanger in response to an operational failure of the liquid cooled heat exchanger. In some such embodiments, the control circuitry triggers activation of the air-cooled heat exchanger in response to a measured temperature of liquid coolant flowing out of the liquid cooled heat exchanger exceeding a threshold temperature, as this parameter (outflowing liquid coolant temperature) is straightforward to monitor and is highly indicative of an operational failure of the liquid cooled heat exchanger. The disclosed single compressor MRI magnet refrigeration system has simplicity compared to a dual-compressor MRI magnet refrigeration system with primary and backup compressors, and has low cost to build compared to a dual-compressor MRI magnet refrigeration system, and requires less maintenance; all while providing substantially comparable protection against failure of the refrigeration system due to compressor failure or malfunction.

In another aspect, in some embodiments the controller of the compressor of the MRI magnet refrigeration system is designed to automatically configure for the MRI magnet to which it is connected. This can be beneficial, for example, in a case where the compressor is designed for use with either liquid helium filled (LHF) or low helium volume (LHV) magnets, since their operation differs and operating one type of magnet using the operational paradigm of the other type of magnet can be detrimental.

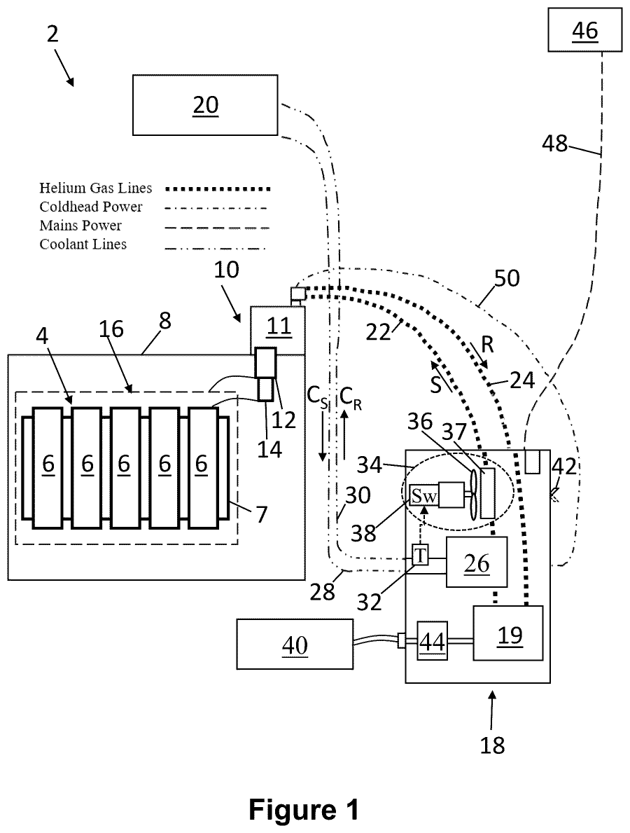

With reference to FIG. 1, an illustrative magnetic resonance imaging (MRI) system or device 2 comprises an MRI scanner (i.e., MRI imaging device), which in the illustrative example includes various components shown in FIG. 1, such as by way of non-limiting illustrative example an MRI magnet 4 comprising a plurality of superconducting coils or windings 6 that generate a static (B₀) magnetic field. The superconducting coils or windings 6 are mounted on a thermally conductive support 7, e.g., made of copper, stainless steel, or the like. The superconducting coils or windings 6 may, by way of one nonlimiting illustrative example, comprise double-pancake coils, which may be disposed in sealed volumes containing a low volume of helium, although it is also contemplated for the MRI magnet 4 to be a helium-free magnet. The MRI magnet 4 is housed within a vacuum vessel 8 that is vacuum-sealed and is evacuated during operation of the MRI magnet. A cryogenic cold head 10 is disposed on and/or in a portion of the vacuum vessel 8. As shown in FIG. 1, the cryogenic cold head 10 includes a motor 11, a first stage cold station 12 which is cooled to a first temperature T₁ (e.g., around 40-80 K in some nonlimiting illustrative embodiments), and a second stage cold station 14 which is cooled to a second temperature T₂ which is lower than T₁ (e.g., T₂ may be around 4 K in some nonlimiting illustrative embodiments). The second stage cold station 14 is thermally connected to the magnet 4 to cool the superconducting windings 6 to the temperature T₂, which is below the superconducting transition temperature of the superconducting windings 6. The magnet 4 in the illustrative example is surrounded by a thermal shield 16 made of a thermally conductive material such as copper or stainless steel, and the first stage cold station 14 is thermally connected to the shield 16 to reduce radiative heat loss from the magnet 4.

FIG. 1 also shows that the MRI device 2 further includes a compressed helium delivery system, including a compressor 18 which includes a motorized helium gas compressor unit 19 configured to compress a working fluid, which is typically helium gas. The compressed helium gas is delivered to the cryogenic cold head 10 by a supply helium gas line 22, and the helium gas is returned to the compressor 18 via a return helium gas line 24. FIG. 1 diagrammatically indicates flow of compressed helium gas from the compressor 18 to the cryogenic cold head 10 by an arrow S, and diagrammatically indicates flow of helium gas back from the cryogenic cold head 10 to the compressor 18 by an arrow R. The compressor 18 also includes a liquid cooled heat exchanger 26 operatively connected to cool the helium gas flowing in the supply helium gas line 22. This is beneficial because the compression of the helium gas by the helium gas compressor unit 19 also heats the helium gas, and the liquid cooled heat exchanger removes at least some of this heat before the compressed helium gas is delivered to the cryogenic cold head 10, thus reducing the thermal load imposed on the cryogenic cold head 10. A supply liquid coolant line 28 is connected to flow liquid coolant, such as chilled water or a chilled water/glycol mixture in some nonlimiting illustrative embodiments, into the liquid cooled heat exchanger 26 from the liquid coolant supply 20 such as a chiller, and a return liquid coolant line 30 is connected to flow the liquid coolant out of the liquid cooled heat exchanger 26 back to the liquid coolant supply 20. FIG. 1 diagrammatically indicates flow of the liquid coolant to the liquid cooled heat exchanger 26 by an arrow C_{S}, and diagrammatically indicates return flow of the liquid coolant from the liquid cooled heat exchanger 26 by an arrow C_{R}. The liquid cooled heat exchanger 26 may have any suitable configuration that keeps the flow of the liquid coolant and the flow of compressed helium physically separated but thermally coupled. For example, the liquid cooled heat exchanger 26 may have a shell-and-tube design in which the helium gas flows through a shell surrounding a tortuous tube within which the liquid coolant flows (or vice versa). In another example, the liquid cooled heat exchanger 26 may have a tube-in-tube design in which the helium gas flows through an inner tube surrounded by an outer tube within which the liquid coolant flows (or vice versa). These are merely some nonlimiting illustrative examples, and other liquid cooled heat exchanger designs are also contemplated.

In some embodiments, a sensor may be provided to monitor operation of the liquid cooled heat exchanger 26. In the illustrative example, this sensor is implemented as a temperature sensor 32 which is arranged to measure a temperature value T of the return liquid coolant line 30. For example, the temperature value T may be mounted on an outside of the return liquid coolant line 30 using thermally conductive solder, paste, or the like. Other types of sensors are also contemplated for monitoring operation of the liquid cooled heat exchanger 26, such as a temperature sensor mounted on the supply helium gas line 22 just downstream of the liquid cooled heat exchanger 26 (not shown).

In addition to the liquid cooled heat exchanger 26, the compressor 18 also includes an air-cooled heat exchanger 34 operatively connected to cool the helium gas flowing in the supply helium gas line 22. As shown in FIG. 1, the air-cooled heat exchanger 34 comprises a fan 36 arranged to drive an airflow across a thermally conductive mass 37 that is thermally connected with the supply helium gas line 22 to provide convective cooling of the thermally conductive mass 37 and thus also of the supply helium gas line 22 that is thermally connected with the mass 37. In some nonlimiting examples, the thermally conductive mass 37 may include heat-sinking fins or other structures (not shown) to increase the total surface area of the thermally conductive mass 37, in order to enhance the convective cooling provided by the air flow generated by the fan 36.

In the illustrative example, the air-cooled heat exchanger 34 is disposed downstream of the liquid-cooled heat exchanger 26 (i.e., “downstream” along the flow path of the compressed helium gas S flowing through the supply helium gas line 22). However, it is alternatively contemplated for the liquid-cooled heat exchanger to be disposed downstream of the air-cooled heat exchanger (variant not shown). More generally, the liquid-cooled heat exchanger 26 and the air-cooled heat exchanger 34 are arranged in series along the supply helium gas line 22. Consequently, the liquid-cooled heat exchanger 26 is capable of cooling the compressed helium gas S flowing through the supply helium gas line 22 so as to reduce thermal load on the cryogenic cold head 10; and likewise, the air-cooled heat exchanger 34 is also capable of cooling the compressed helium gas S flowing through the supply helium gas line 22 so as to reduce thermal load on the cryogenic cold head 10.

However, there are advantages to using the liquid-cooled heat exchanger 26 to cool the compressed helium gas flowing through the supply helium gas line 22, rather than using the air-cooled heat exchanger 34 for this purpose. The water cooled heat exchanger 26 is more efficient and effective at removing the heat produced by the compression of the helium gas. The water cooled heat exchanger 26 also typically runs more quietly than the air-cooled heat exchanger 34, due to fan noise generated by the fan 36. Hence, in some embodiments disclosed herein, the liquid-cooled heat exchanger 26 serves as the primary mechanism for cooling the compressed helium gas flowing through the supply helium gas line 22, and during normal operation the water cooled heat exchanger 26 is operating while the air-cooled heat exchanger 34 is off (i.e., not operating). Only if the water-cooled heat exchanger 26 fails to provide adequate cooling does the air-cooled heat exchanger 34 turn on to supplement or completely replace the water-cooled heat exchanger 26 for the purpose of cooling the compressed helium gas flowing through the supply helium gas line 22.

Toward this end, in some embodiments, the fan 36 is configured to be controlled by an output of the temperature sensor 32 (i.e., a temperature measurement of the return liquid coolant line 30). In the illustrative implementation of this control, the air-cooled heat exchanger 34 includes or is operatively connected with a switch 38 configured to control operation of the fan 36 based on the output of the temperature sensor 32. To do so, when the output of the temperature sensor 32 exceeds or equals a predetermined temperature threshold T_{TH}, the switch 38 controls the fan 36 to start operating. When the output of the temperature sensor 32 underruns the predetermined temperature threshold T_{TH}, the switch 38 controls the fan 36 to stop operating. The rationale for this control paradigm is as follows. If the chiller or other liquid coolant supply 20 fails, the hot compressed helium gas flowing through the supply helium gas line 22 will start heating the return liquid coolant line 30, which is no longer being cooled by flow of chilled water/glycol (or other liquid coolant). The return liquid coolant line 30 is typically made of copper, copper alloy, stainless steel, or another thermally conductive material, and will thus heat up until the temperature of the return liquid coolant line 30 measured by the temperature sensor 32 exceeds or equals the threshold temperature T_{TH}. At that point, the switch 38 is automatically operated to turn the fan 36 on, thus initiating operation of the air cooled heat exchanger 34. When the liquid coolant supply 20 is restored (e.g., the chiller is repaired and operational), the return liquid coolant line 30 is again cooled by flow of chilled water/glycol (or other liquid coolant), thus reducing the temperature of the return liquid coolant line 30. When the temperature of the return liquid coolant line 30 measured by the temperature sensor 32 drops below the threshold temperature T_{TH}, the switch 38 is again automatically operated, this time to turn the fan 36 off thus stopping the air cooled heat exchanger 34.

In the illustrative examples, a single threshold temperature T_{TH} is used for both starting and stopping the fan 36. However, it is alternatively contemplated to employ different thresholds for turning the fan 36 on versus turning it off. For example, the fan 36 may automatically turn on when the temperature of the return liquid coolant line 30 measured by the temperature sensor 32 exceeds a higher temperature threshold T_{TH,H}, and automatically turn off when the temperature of the return liquid coolant line 30 measured by the temperature sensor 32 falls below a lower temperature threshold T_{TH,L}. In this example, T_{TH,H}>T_{TH,L}, and the difference (T_{TH,H}-T_{TH,L}) provides a buffer against the fan 36 being cycled on and off intermittently around the threshold temperature due to small fluctuations in the output of the temperature sensor 32. (Note that the illustrative embodiment employing the single threshold temperature T_{TH} can be considered to be the case where T_{TH,H}=T_{TH,L}=T_{TH}).

In the foregoing examples, the control mechanism is the switch 38 which turns the fan 36 on or off, thus turning operation of the air cooled heat exchanger 34 on or off. However, more complex control paradigms are contemplated. For example, the fan speed of the fan 36 could be gradually ramped up as the temperature measured by the temperature sensor 32 increases toward and/or above the threshold temperature T_{TH}. Likewise, the fan speed of the fan 36 could be gradually ramped down as the temperature measured by the temperature sensor 32 decreases toward and/or below the threshold temperature T_{TH}. This control paradigm would provide a more gradual transition between cooling via the water cooled heat exchanger 26 and cooling via the air cooled heat exchanger 34, and could for example be effective if the failure mode is not a complete loss of coolant in the coolant supply and return lines 28 and 30, but rather a less catastrophic failure such as reduced chilling of the coolant or gradual reduction in coolant flow due to buildup of contamination in the lines 28 and 30 leading to constricted coolant flow over time.

On the other hand, in other contemplated embodiments automated control features of the illustrative compressed helium delivery system may be omitted. For example, rather than having the switch 38 with automated control based on the temperature sensor 32, the compressed helium delivery system could instead include a display showing the readout of the temperature sensor 32, optionally further including a visual and/or audio alarm triggered if the temperature output exceeds the threshold temperature T_{TH}. In such an alternative embodiment, the operator would manually turn on the fan 36 in response to the measured temperature exceeding the threshold temperature T_{TH}. In another variant embodiment, the temperature sensor 32 may also be omitted.

The various disclosed embodiments of the compressed helium delivery system have certain advantages. By including only a single compressor 18, cost and complexity of the compressed helium delivery system is reduced as compared with dual-compressor systems. However, by providing the liquid cooled heat exchanger 26 and the air cooled heat exchanger 34 in series, the most common failure modes of the compressed helium delivery system, namely loss of coolant flow or degradation of the coolant flow (e.g., due to reduced coolant flow rate or reduced chilling) are effectively handled in a manner that substantially extends (potentially indefinitely) the operational window of the MRI system 2 when operation of the liquid cooled heat exchanger 26 is compromised or fails completely. These benefits are particularly valuable in the case of a low helium volume (LHV) magnet, since the reduced helium volume reduces the time window over which the LHV magnet can operate with a compromised compressed helium delivery system. However, these benefits are also beneficial in the case of a liquid helium filled (LHF) magnet, and the disclosed helium delivery system embodiments can be usefully employed in conjunction with either an LHV magnet or an LHF magnet.

In another disclosed aspect, operation of a controller 40 of the compressor 18 is automatically determined based on the type of compressor. In the case of an LHF magnet (not shown), the compressor is run continuously, with a helium bath heater being used to regulate the magnet. In normal operation of an LHF magnet, the continuously running compressor cools the magnet, which causes the helium overpressure within the pressure vessel to decrease. The helium bath heater is then turned on when the helium gas overpressure drops to a low setpoint. The helium bath heater boils off some of the liquid helium (effectively overcoming the cooling provided by the continuously running compressor, so that the helium overpressure in the vacuum vessel of the LHF magnet rises. When the helium overpressure reaches a high setpoint, the helium bath heater turns off, and the continuously running compressor again cools the magnet down. This mode of control in which the compressor is run continuously to provide continuous cooling and the helium bath heater is controlled based on the helium overpressure is referred to herein as pressure control mode (PCM).

By contrast, in the case of an LHV magnet (e.g., as illustrated in FIG. 1), there is no large reservoir of liquid helium. (For example, some nonlimiting illustrative LHV magnet designs may have 10 liters or less of helium). In this case, the compressor 18 may be turned on or off via a manual switch 42 at the front panel of the compressor 18, to provide manual control of whether the compressor 18 is operating the cryogenic cold head 10.

Auto-control mode (ACM) is a function built into some compressors to protect a LHF magnet. The reason for providing ACM is as follows. If a compressor is connected to a LHF magnet but does not have a controller attached, and the compressor is turned on from the front panel switch 42, then the compressor will turn off after one hour. This is ACM. (Note, while in the examples herein ACM turns off the compressor one hour after it is manually turned on via the manual switch 42, more generally ACM turns off the compressor a time interval T_{shutoff} after it is manually turned on via the manual switch 42, where T_{shutoff} is chosen to protect the LFH magnet). The purpose of ACM is to protect a LHF magnet which can be damaged if a compressor is attached without helium bath heater control and runs continuously. This risk is alleviated by the ACM automatically shutting the compressor off a time interval T_{shutoff} after it is manually turned on via manual switch 42. The time interval T_{shutoff} is chosen to be short enough to ensure the magnet cannot go sub-atmospheric due to cooling by the compressor. In summary, it is not desirable for the compressor 18 to be able to be manually turned on using the manual switch 42 when it is running a LHF magnet and there is no controller attached because, in the absence of a controller operating a helium bath heater to turn on to increase the helium overpressure when it drops to a low overpressure setpoint, the LHF magnet could continue to be cooled below that setpoint and go sub-atmospheric causing ice to form.

On the other hand, it is desirable for the compressor 18 to be able to run continuously, controlled by the front panel switch 42, when the compressor 18 is connected to a LHV magnet. This enables the compressor 18 to maintain the lowest possible temperature for the LHV magnet at all times.

It is recognized herein, that operators sometimes get confused, and may turn off the compressor 18 via the manual front-panel on/off switch 42 when the compressor is operating a LHF magnet. To avoid this, in some embodiments disclosed herein, the controller 40 is automatically configured based on which type of magnet (LHF or LHV) is connected.

To control operation of the compressor 18 in these embodiments, the illustrative MRI device 2 includes the controller 40 operatively connected to the compressor 18 via an interlock 44 which detects whether the compressor 18 is operating a LHF magnet or an LVH magnet. When the controller 40 is connected with a compressor 18 operating a LHF magnet, the controller 40 operates the compressor 18 in PCM with ACM active, which protects the LHF magnet by automatically turning the compressor 18 off after one hour if the operator manually switches the compressor 18 on via the manual switch 42. By contrast, when the controller 40 is operatively connected to the compressor 18 operating a LVH magnet, the controller 40 overrides ACM such that the compressor 18 will not turn off after one hour if it is manually turned on from the front panel. This is advantageous since the manual compressor operation may be used to maintain the lowest possible temperature for the LHV magnet at all times.

As shown in FIG. 1, the compressor 18 is connected to an external electrical power supply 46 via a mains power line 48 to supply electrical power to the components thereof described herein. The cold head 10 is connected to the compressor 18 via a cold head power line 50 configured to supply power to the cold head 10.

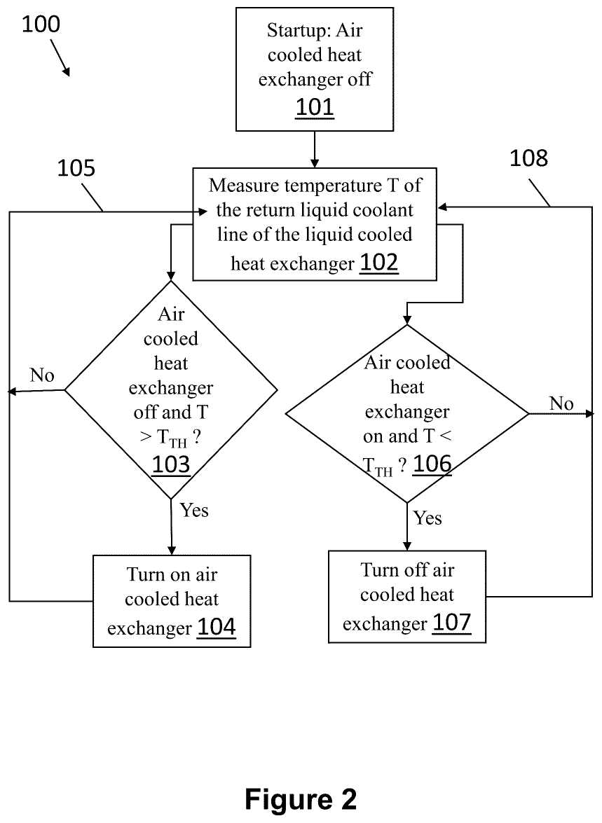

With reference to FIG. 2, and with continuing reference to FIG. 1, an illustrative method 100 of controlling operation of the air cooled heat exchanger 34 is diagrammatically shown as a flowchart. To being the method 100, at an operation 101, the air cooled heat exchanger 34 is initially turned off. At an operation 102, the temperature sensor 32 measures a temperature T of the return liquid coolant line 30 of the liquid cooled heat exchanger 26. At a decision block 103, a controller (not shown) of the switch 38 determines whether the measured temperature value T exceeds (or is equal to) the predetermined temperature threshold T_{TH} (which, in some embodiments, may be the higher threshold T_{TH,H} for decision block 103). If so, this indicates the water-cooled heat exchanger 26 is not providing adequate cooling, and so the air cooled heat exchanger 34 is turned on at an operation 104,, e.g., the switch 38 controls the fan 36 to operate, thereby turning on the air cooled heat exchanger 34 on to cool the compressed helium gas flowing in the supply helium gas line 22. The temperature sensor 32 continuously measures the temperature T, as indicated by the feedback loop 105.

At an operation 106, the controller of the switch 38 determines whether the measured temperature value T underruns the predetermined temperature threshold T_{TH} (which, in some embodiments, may be the lower threshold T_{TH,L} for decision block 106). If so, and the air cooled heat exchanger 34 is turned on, then this indicates the liquid cooled heat exchanger 26 is now providing adequate cooling of the compressed helium gas, and so at an operation 107 the switch 38 controls the fan 36 to stop operating, thereby turning off the air cooled heat exchanger 34. The temperature sensor 32 continuously measures the temperature T, as indicated by the feedback loop 108.

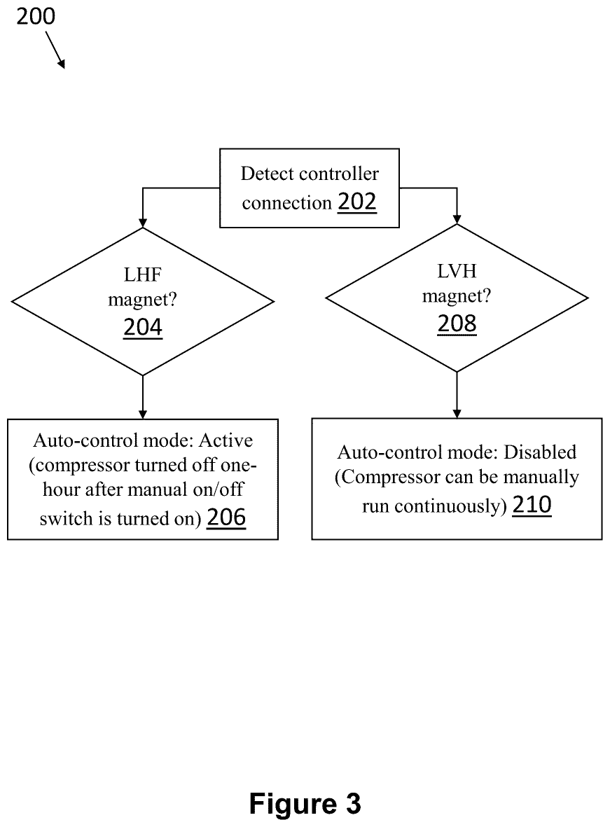

Referring now to FIG. 3, and with continuing reference to FIGS. 1 and 2, optional operations of the method 200 are shown. At an operation 202, a connection of the controller 40 to the compressor 18 via the interlock 44 is detected by the controller 40. At an operation 204, if the operation 202 indicates the controller 40 is connected with a compressor which is operating a LHF magnet, then in an operation 206 the controller 40 operates the compressor 18 with auto-control mode (ACM) enabled, so that the compressor is turned off after one hour (or, more generally, after the time interval T_{shutoff}) to prevent the compressor 18 from potentially driving the LHF magnet helium overpressure sub-atmospheric if it is inadvertently manually turned on via the manual switch 42. Conversely, at an operation 208, if the operation 202 indicates the controller 40 is connected with a compressor which is operating a LVH magnet, then in an operation 210 the controller 40 operates the compressor 18 with ACM disabled, so that the front-panel manual on/off switch 42 of the compressor 18 can be used to run the LVH magnet continuously to maximize cooling if desired by the operator.

The disclosure has been described with reference to the preferred embodiments. Modifications and alterations may occur to others upon reading and understanding the preceding detailed description. It is intended that the exemplary embodiment be construed as including all such modifications and alterations insofar as they come within the scope of the appended claims or the equivalents thereof.

1. An imaging system, comprising:
a magnetic resonance imaging (MRI) vacuum vessel containing an MRI magnet comprising superconducting windings;
a cryogenic cold head connected to cool the superconducting windings;
a compressor configured to compress helium gas;
a supply helium gas line and a return helium gas line connecting the compressor with the cryogenic cold head;
a liquid cooled heat exchanger operatively connected to cool the helium gas flowing in the supply helium gas line;
a supply liquid coolant line connected to flow liquid coolant into the liquid cooled heat exchanger;
a return liquid coolant line connected to flow the liquid coolant out of the liquid cooled heat exchanger; and
an air-cooled heat exchanger operatively connected to cool the helium gas flowing in the supply helium gas line.

2. The imaging system of claim 1, wherein the air cooled heat exchanger is configured to only cool the helium gas flowing in the supply helium gas line.

3. The imaging system of claim 1, further comprising:
a temperature sensor arranged to measure a temperature of the return liquid coolant line;
wherein the air-cooled heat exchanger comprises a fan configured to be controlled by an output of the temperature sensor.

4. The imaging system of claim 3, wherein the air-cooled heat exchanger includes a switch configured to control operation of the fan based on the output of the temperature sensor.

5. The imaging system of claim 4, wherein the switch configured to control operation of the fan by:
when the output of the temperature sensor exceeds or equals a predetermined temperature threshold, controlling the fan to start operating; and
when the output of the temperature sensor underruns a predetermined temperature threshold, controlling the fan to stop operating.

6. The imaging system of claim 5, wherein the predetermined temperature threshold comprises:
an upper temperature threshold (T_{TH,H}) at which the fan starts operating; and
a lower temperature threshold (T_{TH,L}) at which the fan stops operating.

7. The imaging system of claim 1, further comprising:
a controller operatively connected to the compressor to control operation of the compressor.

8. The imaging system of claim 7, wherein the controller is configured to control operation of the compressor based on whether the compressor is connected with a liquid helium filled magnet or a low volume helium magnet.

9. A compressed helium delivery system for a magnetic resonance imaging (MRI) system, comprising:
a compressor configured to compress helium gas;
a supply helium gas line connected to deliver the compressed helium gas from the compressor to a cryogenic cold head of the MRI system;
a liquid cooled heat exchanger operatively connected to cool the helium gas flowing in the supply helium gas line;
supply and return liquid coolant lines connected to flow liquid coolant through the liquid cooled heat exchanger; and
an air-cooled heat exchanger operatively connected to cool the helium gas flowing in the supply helium gas line.

10. The compressed helium delivery system of claim 9, further comprising:
a temperature sensor arranged to measure a temperature of the return liquid coolant line.

11. The compressed helium delivery system of claim 10, wherein the air-cooled heat exchanger comprises a fan configured to be controlled by an output of the temperature sensor.

12. The compressed helium delivery system of claim 11, further comprising a switch configured to turn the fan on or off based on the output of the temperature sensor.

13. The compressed helium delivery system of claim 12, wherein the switch configured to:
turn the fan on in response to the output of the temperature sensor exceeding or equaling a predetermined temperature threshold; and
turn the fan off in response to the output of the temperature sensor underrunning the predetermined temperature threshold.

14. The compressed helium delivery system of claim 13, wherein the predetermined temperature threshold comprises:
an upper temperature threshold (T_{TH,H}) at which the fan turns on; and
a lower temperature threshold (T_{TH,L}) at which the fan turns off.

15. The compressed helium delivery system of claim 9, further comprising:
a controller operatively connected to the compressor to control operation of the compressor.

16. The compressed helium delivery system of claim 15, wherein the controller is configured to control operation of the compressor including disabling a manual on/off switch of the compressor if the compressor is connected with a liquid helium filled magnet.

17. The compressed helium delivery system of claim 9, further comprising:
a return helium gas line connecting the compressor with the cryogenic cold head.

18. The compressed helium delivery system of claim 17, wherein the air cooled heat exchanger is configured to only cool the helium gas flowing in the supply helium gas line.

19. A method of controlling operation of a magnetic resonance imaging (MRI) device, the method comprising:
compressing helium gas using a compressor connected to deliver the compressed helium gas to a cryogenic cold head of the MRI device;
measuring a temperature of a return liquid coolant line of a liquid heat exchanger used to cool the compressed helium gas delivered from the compressor to the cryogenic cold head of the MRI device;
determining whether the measured temperature exceeds or underruns a predetermined temperature threshold;
in response to the measured temperature being determined to exceed the predetermined temperature threshold, turning on a fan of an air cooled heat exchanger to cool the compressed helium gas delivered to the cryogenic cold head of the MRI device; and
in response to the measured temperature being determined to underrun the predetermined temperature threshold, turning off the fan of the air cooled heat exchanger.

20. The method of claim 19, further comprising:
automatically detecting whether the compressor is connected with a liquid helium filled magnet or with a low volume helium magnet;
in response to the compressor being detected to be connected with a sealed magnet, turning off compressor ACM mode; and
in response to the compressor being detected to be connected with a low volume helium magnet, disabling the auto-control mode.
